(19) United States
(12) Patent Application Publication
(10) Pub. No.: US 2012/0201026 A1
(43) Pub. Date: Aug. 9, 2012

(54) LED Module, Method for Operating said LED Module and Lighting Device having said LED Module

(75) Inventor: Nadir Farchtchian, Berlin (DE)

(73) Assignee: OSRAM AG, Munchen (DE)

(21) Appl. No.: 13/501,544

(22) PCT Filed: Sep. 30, 2010
(86) PCT No.: PCT/EP10/64606

§ 371 Date: Apr. 12, 2012

(30) Foreign Application Priority Data
Oct. 12, 2009 (DE) 10 2009 049 057.4

(51) Int. Cl. F21S 6/00; H01L 33/50

(52) U.S. Cl. 362/235; 257/88; 257/E33.06

(57) ABSTRACT

An LED module comprising at least one light emitting diode chip which is arranged on a carrier, wherein the at least one LED chip is configured for operation with a current strength of at least 1.4 amperes.

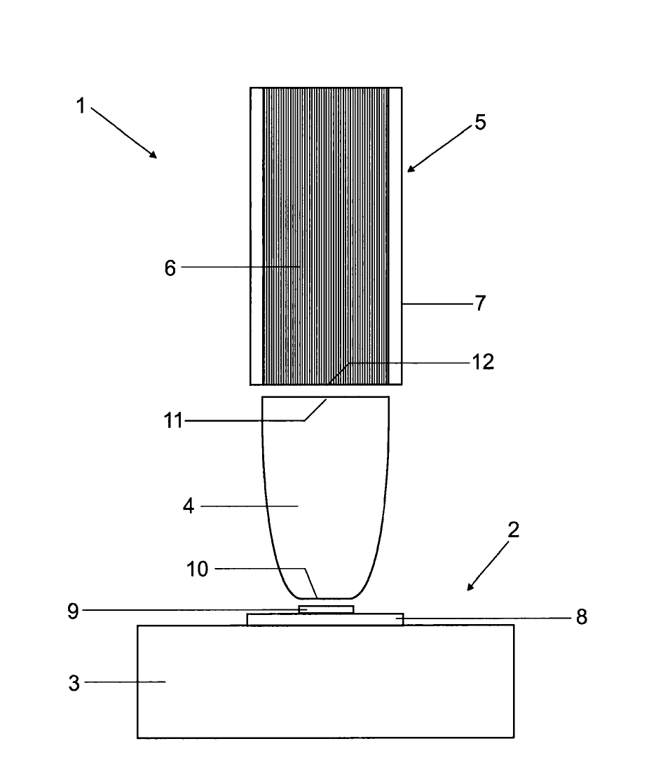

### AREA OF TECHNOLOGY

The invention relates to a module having one or more light emitting diode chips, referred to in the following for short as LED module (LED: light emitting diode). The term light emitting diode chip here denotes the part of an LED which generates light.

The invention also relates to a lighting device having said LED module, whereby this lighting arrangement having the LED module is intended for use with elongated light conductors. These include in particular fiber optic applications amongst other things for medical or industrial diagnostics, monitoring and operation such as for example endoscopy, boroscopy and microscopy.

### Prior Art

Hitherto, predominantly halogen or discharge lamps, in particular xenon discharge lamps having an output of approx. 100 to 300 W, have been employed both for endoscopes and also for boroscopes. Infrared filters are employed between lamp and light conductor in order to reduce the thermal load caused by the light of said lamps exiting from the endoscope or boroscope. In addition, the light from the lamps is focused by means of suitable reflectors onto the entry surface of the elongated light conductor. The high light density on the entry surface which can be achieved in this situation is crucial for the functionality of the system.

The optical fiber bundles which are employed as light conductors for endoscopy, boroscopy and microscopy typically have a diameter of less than five millimeters and a numerical aperture of typically 0.5 to 0.7. In addition, typical light densities of 80·10⁶ cd/m² and more are required for the aforementioned intended purposes. A replacement of conventional lamps on the basis of LEDs presupposes a compact LED arrangement having a very high light density.

### STATEMENT OF THE INVENTION

The object of the present invention is to specify an LED module which is suitable for coupling-in light in thin light conductors, in particular in fiber optic systems.

A further aspect of the invention, on the basis of this LED module, is to provide a lighting device having a light coupler, which achieves a sufficiently high light density, in particular for endoscopy, boroscopy and microscopy, at the input of an elongated light conductor, for example a fiber bundle or a liquid light guide.

In addition, protection is sought for a method for operating the LED module according to the invention and also for the use thereof for endoscopes, boroscopes and microscopes.

This object is achieved by an LED module having at least one light emitting diode (LED) chip which is arranged on a carrier, characterized in that the at least one LED chip is designed for operation with a current strength of at least 1.4 amperes.

With regard to the lighting device, the operating method and the use of the LED module according to the invention, reference is made to the respective independent claims directed thereto.

Particularly advantageous embodiments are set down in the respective dependent claims.

The fundamental idea of the invention, with regard to an LED module, consists in achieving the high light density of typically 80·10⁶ cd/m² and more required for light conductor applications such as endoscopy, boroscopy and microscopy by means of at least one LED chip which is designed for an operating current of at least 1.4 amperes.

It has furthermore proved advantageous if the surface area of the chip of the at least one LED measures at least 1.5 mm². For some light conductor applications it can moreover be advantageous to arrange two or more LED chips close to one another to form an array in order in this manner to obtain a correspondingly large light emitting surface area.

It is furthermore preferred that the LED chip be arranged directly on the carrier. The heat dissipation from the LED chip can be improved by this means because the carrier preferably consists of a material, copper for example, which conducts heat particularly well. In addition, the LED carrier is preferably arranged on a heat sink which dissipates the heat loss from the LED(s) particularly well to the environment or a cooling agent. It is furthermore preferred that the individual LED chip has neither a housing nor a primary lens. This means that it is also possible to arrange two or more LED chips relatively close to one another to form an LED array (multi-chip on board technology). In this situation, it may possibly be advantageous in order to afford protection against external influences to provide the LED array overall with a housing or a protective coating, a glass guard or similar.

Generally, according to the invention LED chips of the surface emitter type are preferred in which the predominant part, typically more than 90%, is emitted over the upper top surface of the LED chip. In this situation, the LED chips in question in particular employ thin-film technology (such as for example OSRAM ThinGaN®). Preferred are LED chips which emit light having a spectral half width of greater than or equal to 50 nm, in particular also white light, by means of phosphor conversion, for example LEDs of the ultra-white or warm white types from the OSRAM Opto Semiconductor company. In principle, depending on the area of application, LED chips emitting not only light visible to the human eye but also ultraviolet (UV) or infrared (IR) radiation may also be considered.

A lighting device according to the invention comprises the LED module described above and also a light coupler. The light coupler is designed for example as a non-imaging optical element and comprises a coupling-in surface and a coupling-out surface. In this situation, the light coupler is arranged such in relation to the LED module that the light emitted by the LED or the LED array during operation couples into the coupling-in surface of the light coupler.

In a development, the coupling-in surface of the light coupler is smaller than the coupling-out surface. In order to keep coupling-in losses as low as possible, it can be advantageous to form the coupling-in surface of the light coupler in rectangular fashion and to match it to the LED chip surface area or the total surface area of the LED array. In order to further reduce the coupling-in losses, the coupling-in surface and/or the coupling-out surface can be provided with an antireflection coating. In order to be able to achieve a light density of 80·10⁶ cd/m² and more required during operation for many fiber optic applications such as endoscopy, boroscopy or microscopy when using the LED module according to the invention, provision is made to operate the at least one LED chip or where applicable each LED chip of the LED array with a current greater than or equal to 1.4 amperes.

Depending on the target level for the value for the light density at the end of the light conductor, provision is made as required to arrange a suitable number of LED chips having maximum operating currents of at least 1.4 amperes in a dense LED array. With the aid of the light coupler, in particular a non-imaging optical element, of the lighting device according to the invention, the light emitted by this LED array is coupled into the light conductor.

The lighting device described above is preferably intended for use in an endoscope, boroscope or microscope.

### BRIEF DESCRIPTION OF THE DRAWING

The invention will be described in detail in the following with reference to an exemplary embodiment. In the drawing, the single FIGURE:

FIGURE shows a lighting device having an LED module according to the invention and an elongated light conductor.

### PREFERRED EMBODIMENT OF THE INVENTION

The single FIGURE shows a highly schematic side view of a lighting device 1 according to the invention for use in an endoscope. The lighting device 1 consists of an LED module 2, a heat sink 3 on which the LED module 2 is arranged, and a light coupler 4. Likewise illustrated is a light conductor 5 having optical fibers 6 which are enclosed by a cladding 7. The LED module 2 of the Power-OSTAR type from the OSRAM Opto Semiconductor company comprises a plate-shaped carrier 8 made of copper with a gold-plated surface and a total of four LED chips 9. Each of the four LED chips 9 has a surface area of 2 mm² and emits white light when operating. To provide better heat dissipation, the four LED chips 9 are soldered directly on the side of the carrier 8 facing away from the heat sink 3. In this situation, the four LED chips 9 are arranged at a distance from one another of 70 μm to form a 202 array densely packed on the carrier 8. Each of the four LED chips 8 is controlled separately by a drive electronics unit with a DC current of up to 6 amperes (not illustrated). A light density of greater than 80·10⁶ cd/m² is thereby attained. For dimming purposes the light density of the LED can be set between 5% and 100%. The light coupler 4 is designed as an elongated, non-imaging optical element with a coupling-in surface 10 facing the four LED chips 9 and a coupling-out surface 11 facing the input of the light conductor 5. An air gap is provided in each case between coupling-in surface 10 and LED chips 4 on the one hand and between coupling-out surface 11 and light conductor 5 on the other hand. The air gap is necessary for adjustment and mechanical tolerances and should not exceed 0.5 mm in order to minimize the losses. The coupling-in surface 10 of the light coupler 4 is a little larger than the total surface area of the LED array consisting of the four LED chips 9. In the present exemplary embodiment, the cross-section of the light coupler is circular. In order to further improve the coupling-in efficiency, the cross-section of the light coupler can also be matched to the rectangular total surface area of the LED array. The coupling-out surface 11 of the light coupler 4 is matched to the entry surface 12 of the light conductor 5 and is a little larger than the coupling-in surface 10.

1. An LED module comprising:
at least one light emitting diode chip which is arranged on a carrier, wherein
the at least one LED chip is configured for operation with a current strength of at least 1.4 amperes.

2. The LED module as claimed in claim 1, wherein the surface area of the at least one LED chip measures at least 1.5 mm².

3. The LED module as claimed in claim 1, wherein two or more LED chips are arranged close to one another to form an LED array.

4. The LED module as claimed in claim 1 wherein at least one phosphor is provided which converts the light from the at least one LED chip into light having a spectral half width of greater than or equal to 50 nm.

5. The LED module as claimed in claim 1, wherein at least one LED chip emits ultraviolet or infrared radiation.

6. A lighting device having an LED module as claimed in claim 1 and a light coupler having a coupling-in surface and a coupling-out surface, wherein the light coupler is arranged such in relation to the LED module that the light emitted by the at least one LED chip during operation couples into the coupling-in surface of the light coupler.

7. The lighting device as claimed in claim 6, wherein the coupling-in surface of the light coupler is smaller than the coupling-out surface thereof.

8. The lighting device as claimed in claim 6, wherein the coupling-in surface of the light coupler is formed in rectangular fashion and is matched to the surface area of the at least one LED chip.

9. The lighting device as claimed in claim 6, wherein the coupling-in surface and/or the coupling-out surface is/are provided with an antireflection coating.

10. The lighting device as claimed in claim 6, wherein the light coupler is configured as a non-imaging optical element.

11. A method for operating an LED module as claimed in claim 1, wherein the at least one LED chip or where applicable each LED chip is operated with a current greater than or equal to 1.4 amperes.

12. The method as claimed in claim 11, wherein the level of the current and/or the number of LED chips (9) is chosen such that a light density of at least 80·10⁶ cd/m² is attained.

13. (canceled)

14. (canceled)

15. (canceled)
